(19) United States
(12) Patent Application Publication
(10) Pub. No.: US 2011/0036386 A1
(43) Pub. Date: Feb. 17, 2011

(54) SOLAR PANEL WITH INVERTER

(76) Inventor: John H. Browder, Roanoke, TX (US)

Correspondence Address: CARSTENS & CAHOON, LLP, 13760 NOEL ROAD, SUITE 900, DALLAS, TX, 75240, US

(21) Appl. No.: 12/542,600

(22) Filed: Aug. 17, 2009

(51) Int. Cl. H01L 31/042

(52) U.S. Cl. 136/244

(57) ABSTRACT

The system of the present invention comprises a fully integrated and self-contained alternating current (“AC”) photovoltaic (“PV”) solar panel device, which features an integral micro-inverter having a compression connector fitting for electrically connecting to the utility grid. The compression connector fitting includes an upper and lower housing, which each include a cavity portion for receiving the main electrical conductor wire. The connector fitting further includes three electrical prong devices, which are designed to penetrate the insulation of the main electrical conductor wire, upon compression onto the main electrical conductor wire. Each micro-inverter converts DC power generated by its respective solar panel to grid-compliant AC power.

### BACKGROUND OF THE INVENTION

1. Technical Field of the Invention

The present invention relates to systems for utilizing power generated by solar panels, and more particularly, to an improved modularized photovoltaic system. The invention provides a fully integrated and self-contained alternating current (“AC”) photovoltaic (“PV”) solar panel device and method that allows photovoltaic applications to become true plug-and-play devices.

2. Description of the Related Art

Most of today's solar photovoltaic (PV) power sources are utility connected. About 75% of these installations are residential rooftop systems with less than 2 kW capability. These systems typically comprise a number of PV modules arranged in series configuration to supply a power converter, commonly called an inverter, which changes the direct current (DC) from the modules to alternating current (AC) to match the local electrical utility supply.

The following U.S. patents relate generally to the state of the art in photovoltaic systems U.S. Pat. No. 6,219,623, to Wills; U.S. Pat. No. 6,285,572, to Onizuka; U.S. Pat. No. 6,201,180, to Meyer; U.S. Pat. No. 6,143,582, to Vu; U.S. Pat. No. 6,111,189, to Garvison; U.S. Pat. No. 6,046,400, to Drummer; U.S. Pat. No. 5,730,495, to Barone; and U.S. Pat. No. 5,702,963, to Vu.

In the case of a single module system producing AC power output, the photovoltaic module is connected to the inverter or load through a junction box that incorporates a fuse to protect the photovoltaic module if backfeeding from other sources (e.g., a power utility or a battery) is possible. The photovoltaic modules used in these systems are configured either with a frame or without a frame. Frameless photovoltaic modules are generally referred to as a laminate. For conventional systems that utilize multiple laminates or modules, the laminates or modules are interconnected via junction boxes or flying leads and external wiring that must be rated sunlight resistant and sized to carry the rated currents. Some conventional photovoltaic system installations require that the direct current (“DC”) and AC wiring be installed in properly sized and anchored conduit.

A typical method of interconnecting the DC circuits in a conventional photovoltaic system is to have a J-box at the top of each photovoltaic module that provides the terminal block to connect the module circuit to flying-lead conductors that are then fitted with a connector. The J-box also houses the series or “blocking” diode often required by codes and standards to protect the module, especially if more than two strings of modules are paralleled at the combiner box or at the inverter. The module is often constructed with a bypass diode(s) that is(are) usually required for conventional photovoltaic applications. This arrangement is used to connect modules in series. Modules are connected in series until the summed operating voltage is within the optimum DC voltage window of the central or string inverter. The connections are typically made under the modules by plugging connectors together or at distributed junction boxes. Some installations leave insufficient space to allow the installer to make the connections reliably. The central inverter can generally handle multiple strings of photovoltaic modules that are then wired in parallel in a string-combiner assembly or box before DC power is fed to the inverter.

The installation of such a system is quite complicated and typically requires the services of a licensed electrician or certified solar installer. A typical installation usually requires the following steps: 1) attaching a support rack to the roof; 2) attaching solar panel arrays to the support rack; 3) adding a circuit breaker to the main electrical system; 4) adding an electrical line from main electrical panel external to AC disconnect; 5) adding an electrical line from AC disconnect to inverter; 6) adding an electrical line from inverter to DC disconnect; 7) adding an electrical line from DC disconnect to combiner box; 8) adding an electrical line from the combiner box to the roof; 9) adding an electrical line to the first and last solar panel array in the string; and 10) adding electrical connections between the solar panel arrays.

There is also a difficulty with small solar power systems on residential rooftops. Gables and multiple roof angles make it difficult on some houses to obtain enough area having the same exposure angle to the sun for a system of 2 kW. A similar problem arises where trees or gables shadow one portion of an array, but not another. In these cases the DC output of the series string of modules is reduced to the lowest current available from any cell in the entire string. This occurs because the PV array is a constant current source unlike the electric utility, which is a constant voltage source.

An inverter that economically links each PV module to the utility grid can solve these problems as the current limitation will then exist only on the module that is shaded, or at a less efficient angle and does not spread to other fully illuminated modules. This arrangement can increase total array output by as much as two times for some configurations. Such a combination of a single module and a microinverter is referred to as a PV AC module. The AC output of the microinverter will be a constant-current AC source that permits additional units to be added in parallel.

While a variety of proposals directed at PV AC modules have previously been made, none have includes a simple efficient means for connecting to the utility grid. Prior art models of PV AC modules suffer poor reliability owing to early failure of the electrolytic capacitors that are used to store the solar cell energy before it is converted to AC. The capacitor aging is a direct consequence of the high temperature inherent in rooftop installations. Moreover, such PV AC modules do not include a simple and efficient means for connection to the utility grid. A need, therefore, exists for an improved and more efficient method and apparatus for safely connecting such PV AC modules to the electrical utility grid.

### SUMMARY OF THE INVENTION

The present invention overcomes many of the disadvantages of prior art photovoltaic (“PV”) solar panel devices by providing fully integrated and self-contained alternating current (“AC”) photovoltaic (“PV”) solar panel device, which features an integral micro-inverter having a compression connector fitting for electrically connecting to the utility grid. The compression connector fitting includes an upper and lower housing, which each include a cavity portion for receiving the main electrical conductor wire. The connector fitting further includes three electrical prong devices, which are designed to penetrate the insulation of the main electrical conductor wire, upon compression onto the main electrical conductor wire. In one embodiment, the connector fitting is fixably attached to the main electrical conductor wire by means of compressively crimping the connector fitting onto the main electrical conductor wire. In another embodiment, the connector fitting may comprise a snap together device, wherein the upper and lower housing snap together compressing the main electrical conductor wire between them. In still another embodiment, the connector fitting may include fasteners (e.g., bolts and helical screws) for mechanically coupling the connector fitting about the main electrical conductor wire.

The micro-inverters are configured on the back of each solar panel. Each micro-inverter converts DC power generated by its respective solar panel to grid-compliant AC power and are known to exhibit high conversion efficiency. Moreover, there are no moving parts to wear out or maintain.

In addition, unlike prior art string systems, the solar panels of the present invention operate a maximum power point tracking (MPPT), increasing energy output 5-25%. They also exhibit an increased resilience to shade, dust and debris and are capable of high levels of power production even in variable light conditions. By incorporating a micro-inverter into each solar panel, each solar panel produces power independently of the others; thus, eliminating the possibility that a single point failure will disable the entire system. The micro-inverters have a very low internal temperature rise and a long lifetime. They also eliminate the space, heat, noise and visual concerns with large string inverter systems.

Furthermore, they are easy to install and dramatically reduced installation cost, time and space. The system of the present invention offers maximum flexibility in that solar panels can be easily added in any quantity, orientation, location even to any existing solar system.

In accordance with one feature of the invention, a method of installation is disclosed which includes the following steps: 1) attach a support rack to a roof; 2) attach a plurality of solar panels to the rack; 3) add a circuit breaker to the main electrical system; 4) add electrical line from main electrical panel to roof; and 5) crimp panel connectors onto main electrical conductive line.

### BRIEF DESCRIPTION OF THE DRAWINGS

A more complete understanding of the method and apparatus of the present invention may be had by reference to the following detailed description when taken in conjunction with the accompanying drawings, wherein:

FIG. 1 is a perspective view of an embodiment of the solar panel system of the present invention;

FIG. 2 is a front elevation view of an embodiment of a solar panel of the present invention;

FIG. 3 is a back elevation view of an embodiment of a solar panel of the present invention;

FIG. 4 depicts the micro-inverter device attached to the solar panel of the present invention

FIG. 5 is a close-up, cross-sectional view of the main electrical conductor line of the present invention; and

FIG. 6 is a close-up, cross-sectional view of the electrical connector device and main electrical conductor line of the present invention;

Where used in the various figures of the drawing, the same numerals designate the same or similar parts. Furthermore, when the terms “top,” “bottom,” “first,” “second,” “upper,” “lower,” “height,” “width,” “length,” “end,” “side,” “horizontal,” “vertical,” and similar terms are used herein, it should be understood that these terms have reference only to the structure shown in the drawing and are utilized only to facilitate describing the invention.

All figures are drawn for ease of explanation of the basic teachings of the present invention only; the extensions of the figures with respect to number, position, relationship, and dimensions of the parts to form the preferred embodiment will be explained or will be within the skill of the art after the following teachings of the present invention have been read and understood. Further, the exact dimensions and dimensional proportions to conform to specific force, weight, strength, and similar requirements will likewise be within the skill of the art after the following teachings of the present invention have been read and understood.

### DETAILED DESCRIPTION OF THE INVENTION

The present invention overcomes many of the prior art problems associated with solar arrays. The advantages, and other features of the systems and methods disclosed herein, will become more readily apparent to those having ordinary skill in the art from the following detailed description of certain preferred embodiments taken in conjunction with the drawings which set forth representative embodiments of the present invention and wherein like reference numerals identify similar structural elements.

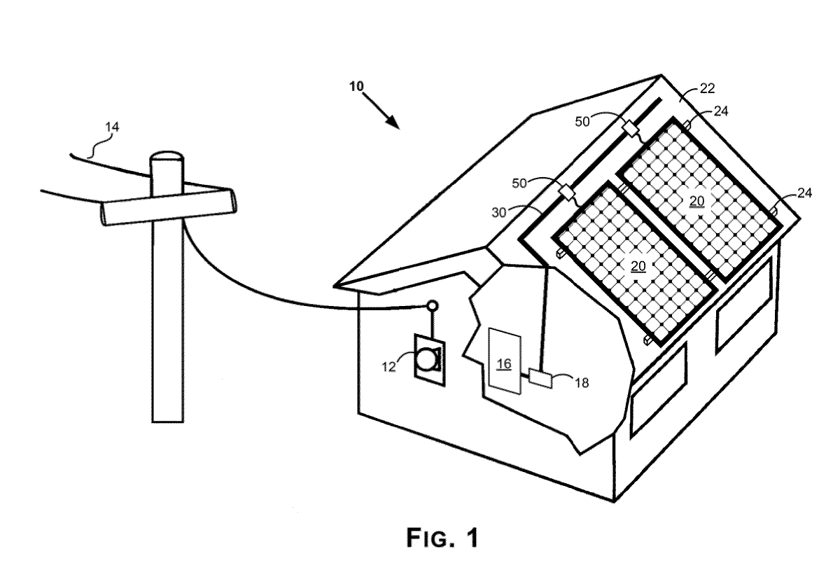

With reference to the Figures, and in particular to FIG. 1, an embodiment of the system 10 of the present invention is depicted. The system 10 includes one or more solar panels 20 mounted on a support rack 24 configured on the roof 22 of a building. The support rack 22 may comprise wooden boards or metal tubing sufficient to displace the solar panels 20 above surface of the roof 22. Suspending the solar panels 20 above the surface of the roof 22 allows air to freely circulate beneath the solar panels 20.

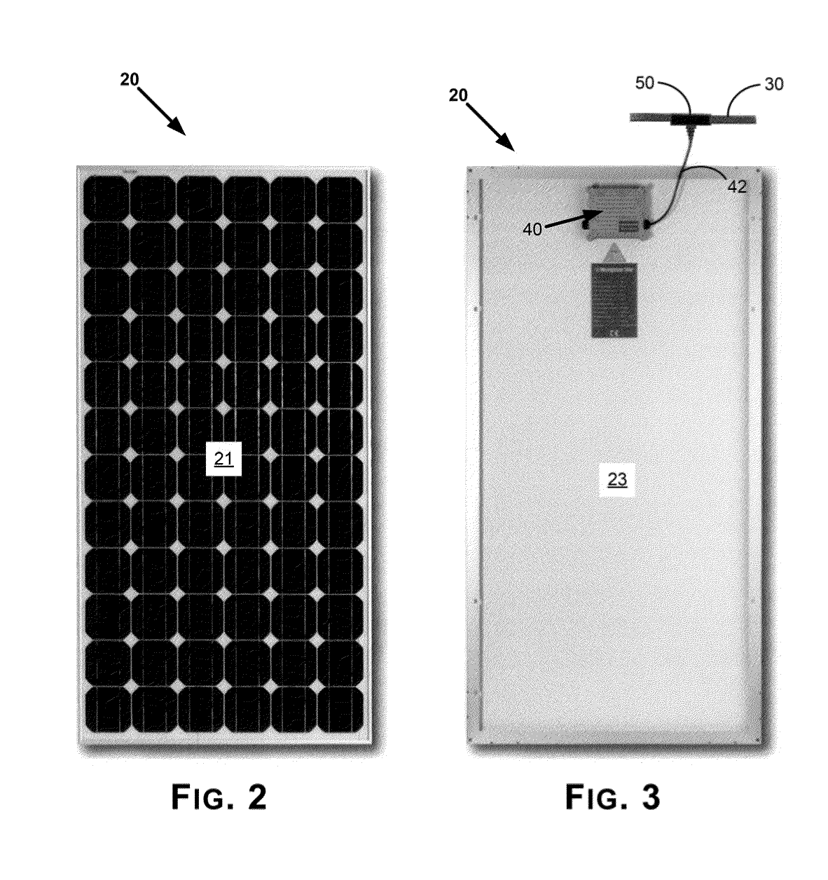

As shown in FIGS. 2 and 3, each solar panel 20 include a front or facing side 21, which is covered with a photovoltaic material. Each solar panel 20 further includes a fully integrated and self-contained micro-inverter device 40, which converts DC power generated by its respective solar panel into grid-compliant AC power. The solar panels 20 are preferably capable of generating 180-200 W of electrical power. The integral micro-inverter device 40 is configured on the back or underside 23 of the solar panel 20. Micro-inverter device 40 has high conversion efficiency, but no moving parts to wear out or maintain. Moreover, the micro-inverter device 40 exhibits very low internal temperature rise and long lifetime.

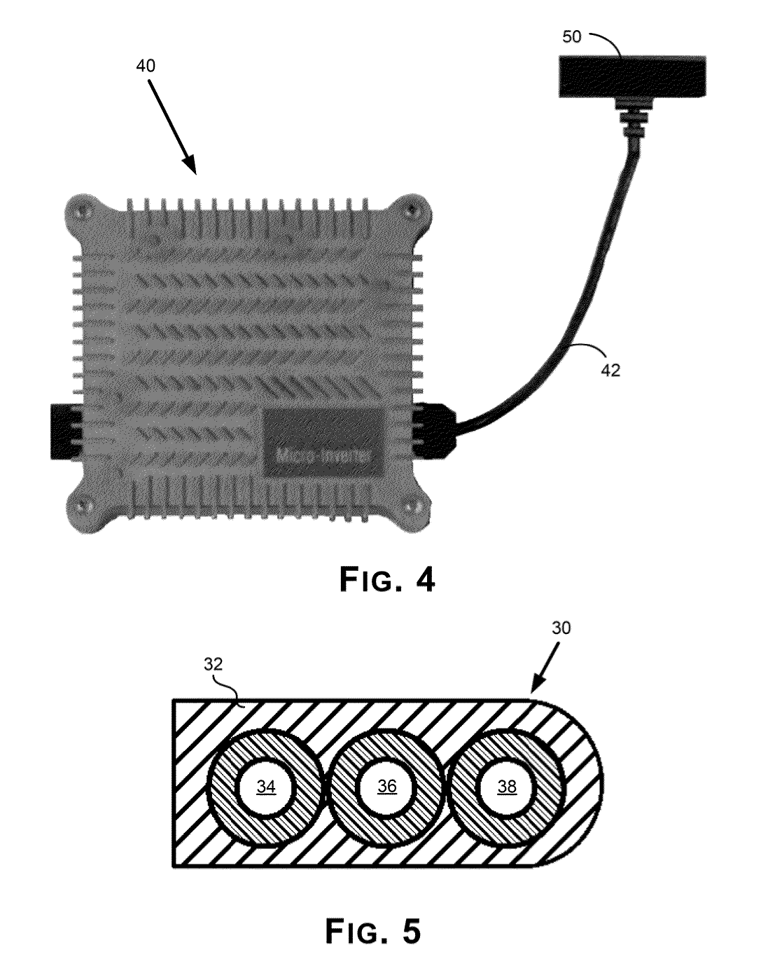

As shown in FIG. 4, each micro-inverter device 40 includes an insulated wire 42 extending therefrom, and having an electrical connector device 50 on a distal end. The electrical connector device 50 includes a compression fitting that electrically connects the micro-inverter device 40 to the utility grid system. Each connector device 50 is selectively connected to the utility grid system by means of a main electrical conductor line 30.

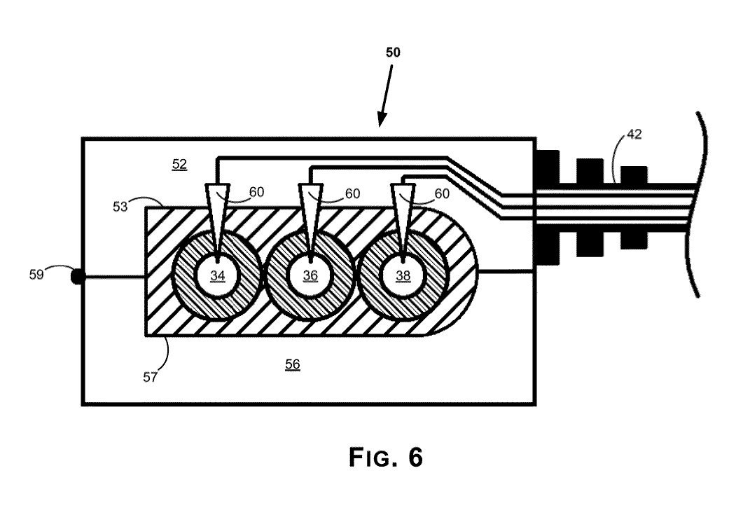

In one embodiment, the main electrical conductor line 30 comprises a heavily clad electrical conductor connected to the utility grid system. For example, with reference to FIG. 5, in a preferred embodiment, the main electrical conductor line 30 comprises a jacketed, three conductor wires 34, 36, 38. The main electrical conductor line 30 is connected to a main electrical panel 16, which in turn is electrically connected to the utility power grid 14 via an electric meter 12. An optional monitor device 18 may also be included in the electrical circuit. In a preferred embodiment, the main electrical conductor line 30 comprises three (3) conductor, 12 AWG, PVC Jacket Conductor rated at 600 Volts.

With reference now to FIG. 6, which depicts a cross-sectional view of the main electrical conductor line 30 positioned within an electrical connector device 50, which includes a compression fitting that electrically connects the micro-inverter device 40 to the utility grid system. For example, in one embodiment the electrical connector device 50, includes a lower portion 56 having a cavity 57 formed therein, and an upper portion 52 having a cavity 53 formed therein; such that when the lower 56 and upper 52 portions are configured as depicted in FIG. 6, the main electrical conductor line 30 is surrounded by the electrical connector device 50. The electrical connector device 50 may further include a pivotal hinge device 59 formed therein that allows the upper 52 and lower 56 portions to pivot relative to one another so as to allow the main electrical conductor line 30 to be captured between the e upper 52 and lower 56 portions prior to compression of the connector device 50 around the conductor line 30. The electrical connector device 50 also includes three prongs 60 which pierce the cladding and insulation surrounding the three conductor wires 34, 36, 38 pierce creating an electrical connection between the micro-inverter device 40 and the utility power grid 14.

In one embodiment, the connector fitting 50 is fixably attached to the main electrical conductor wire by means of compressively crimping the connector fitting 50 onto the main electrical conductor wire. In another embodiment, the connector fitting 50 may simply snap together in compressive bond, wherein the lower 56 and upper 52 portions snap together compressing the main electrical conductor wire between them. In still another embodiment, the connector fitting may include fasteners (e.g., bolts and screws) (not shown) for mechanically coupling the connector fitting about the main electrical conductor wire.

Thus, when sunlight shines on them, each solar panel 20 generates DC electrical power, which is converted into grid-compliant AC electrical power by its respective micro-inverter device 40. Because each solar panel 20 produces power independently of the others, the failure of one solar panel does not adversely affect power output of the remaining solar panels. Moreover, the present invention is capable of operating at a maximum power point tracking (MPPT), thereby increasing energy output 5-25%.

The maximum number of solar panels attached to a system is dictated by the size of the main electrical conductor line 30 and the limit of the circuit breaker in the main electrical panel 16. For example, utilizing a 15 amp breaker in conjunction with 14 gauge wire allows up to nine (9) solar panels 20 to be connected to the main electrical conductor line 30, while utilizing a 20 amp in conjunction with 12 gauge wire allows up to twelve (12) solar panels 20 to be connected to the a main electrical conductor line 30.

In accordance with the method of the present invention, the installation of the present system is greatly simplified and does not require a licensed electrician or certified solar installer to successfully and safely install. The method includes the following steps:
1) attach a support rack 24 to a roof 22;
2) attach a plurality of solar panels 20 of the present invention to the rack 24;
3) adding a circuit breaker to the main electrical panel 16;
4) adding a main electrical conductor line 30 from main electrical panel 16 to roof 22; and
5) compressing or crimping the panel connector fittings 50 onto main electrical conductor line 30.

The system 10 of the present invention eliminates the space, heat, noise and visual concerns with large string inverter systems. Moreover, it exhibits an increased resilience to shade, dust and debris while producing high levels of electrical power even in variable light conditions. Because of the ease and simplification in connecting the connector fittings 50 onto main electrical conductor line 30 the resulting installation costs, time and space are dramatically reduced. Moreover, the system offers maximum flexibility in that the solar panels 20 can be easily added in any quantity, orientation, location even to any existing solar system.

It will now be evident to those skilled in the art that there has been described herein an improved modularized photovoltaic system. The invention provides a fully integrated and self-contained alternating current (“AC”) photovoltaic (“PV”) solar panel device and method that allows photovoltaic applications to become true plug-and-play devices. Although the invention hereof has been described by way of a preferred embodiment, it will be evident that other adaptations and modifications can be employed without departing from the spirit and scope thereof. The terms and expressions employed herein have been used as terms of description and not of limitation; and thus, there is no intent of excluding equivalents, but on the contrary it is intended to cover any and all equivalents that may be employed without departing from the spirit and scope of the invention.

We claim:

1. A system for generating alternating current comprising:
a plurality of solar panels electrically connected to a main electrical conductor line, each of said plurality of solar panels comprise a photovoltaic surface electrically connected to a micro-inverter attached to said panel, wherein said micro-inverter includes a compression connector fitting for electrically connecting said micro-inverter to said main electrical conductor line.

2. The system of claim 1, said compression connector fitting includes an upper and a lower portion for capturing said main electrical conductor line therebetween and three prongs for electrically connecting said micro-inverter to said main electrical conductor line.

3. The system of claim 2, wherein said compression connector fitting is electrically connected to the main electrical conductor line by means of crimping said fitting onto said main electrical conductor line.

4. The device of claim 2, wherein said compression connector fitting is electrically connected to the main electrical conductor line by means of snapping together the upper and lower portions of said compression connector fitting.

5. The device of claim 2, wherein said compression connector fitting is electrically connected to the main electrical conductor line by compressing the upper and lower portions of said compression connector fitting over said main electrical conductor line by means of a mechanical fastener device.

6. The device of claim 5, wherein said mechanical fastener device is a helical screw.
